(19) United States
(12) Patent Application Publication
(10) Pub. No.: US 2026/0076094 A1
(43) Pub. Date: Mar. 12, 2026

(54) PIEZOELECTRIC DEVICE AND PIEZOELECTRIC FILTER

(71) Applicant: Murata Manufacturing Co., Ltd., Nagaokakyo-shi (JP)

(72) Inventor: Yutaka KISHIMOTO, Nagaokakyo-shi (JP)

(21) Appl. No.: 19/395,286

(22) Filed: Nov. 20, 2025

Related U.S. Application Data
(63) Continuation of application No. PCT/JP2024/014875, filed on Apr. 12, 2024.

(30) Foreign Application Priority Data
Jul. 3, 2023 (JP) 2023-109119

(51) Int. Cl. H10N 30/50; H03H 9/02; H03H 9/205; H03H 9/56; H10N 30/87

(52) U.S. Cl. CPC H10N 30/508; H03H 9/02133; H03H 9/205; H03H 9/566; H10N 30/872; H10N 30/877

(57) ABSTRACT

A piezoelectric device includes a piezoelectric layer including a thickness in a first direction, and upper and lower surfaces, a support on a side of the lower surface of the piezoelectric layer, an upper electrode on the upper surface of the piezoelectric layer, a lower electrode on the lower surface of the piezoelectric layer with at least a portion of the lower electrode facing the upper electrode, and a reinforcement film on at least one of the upper and lower surfaces of the piezoelectric layer. The support includes a space portion in a region overlapping with at least a portion of the upper and lower electrodes. In plan view seen in the first direction, the reinforcement film overlaps with at least a portion of a border between a region overlapping with the space portion and a region not overlapping with the space portion.

### CROSS REFERENCE TO RELATED APPLICATIONS

This application claims the benefit of priority to Japanese Patent Application No. 2023-109119 filed on Jul. 3, 2023 and is a Continuation application of PCT Application No. PCT/JP2024/014875 filed on Apr. 12, 2024. The entire contents of each application are hereby incorporated herein by reference.

### BACKGROUND OF THE INVENTION

### 1. Field of the Invention

The present invention relates to piezoelectric devices and piezoelectric filters.

### 2. Description of the Related Art

U.S. Patent Application Publication No. 2012/0205754 describes a piezoelectric device where plate-shaped drive electrodes are provided at respective surfaces of a piezoelectric layer so as to face each other.

The piezoelectric device according to U.S. Patent Application Publication No. 2012/0205754 is provided with a space portion, and in this case, the piezoelectric layer may be damaged at the border between a region overlapping with the space portion and a region not overlapping with the space portion in plan view seen in a direction along the thickness of the piezoelectric layer.

### SUMMARY OF THE INVENTION

Example embodiments of the present invention provide piezoelectric devices and piezoelectric filters each able to reduce or prevent damage to a piezoelectric layer.

A piezoelectric device according to an example embodiment of the present invention includes a piezoelectric layer including a thickness in a first direction and including an upper surface as one of surfaces in the first direction and a lower surface as another one of the surfaces in the first direction, a support on a side of the lower surface of the piezoelectric layer, an upper electrode on the upper surface of the piezoelectric layer, a lower electrode on the lower surface of the piezoelectric layer with at least a portion of the lower electrode facing the upper electrode, and a reinforcement film on at least one of the upper surface and the lower surface of the piezoelectric layer, in which the support includes a space portion in a region overlapping with at least a portion of the upper electrode and the lower electrode, and in plan view seen in the first direction, the reinforcement film overlaps with at least a portion of a border between a region overlapping with the space portion and a region not overlapping with the space portion.

A piezoelectric filter according to an example embodiment of the present invention includes a filter device including at least one resonator, and the resonator includes a piezoelectric device according to an example embodiment of the present invention.

Example embodiments of the present invention provide piezoelectric devices and piezoelectric filters each able to reduce or prevent damage to a piezoelectric layer.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view showing an exemplary electrode provided on an upper surface of a piezoelectric layer according to a first example embodiment of the present invention.

FIG. 2 is a schematic plan view showing an exemplary electrode provided on a lower surface of the piezoelectric layer according to the first example embodiment of the present invention.

FIG. 3 is a schematic sectional view taken along line III-III in FIG. 1.

FIG. 4 is a schematic sectional view illustrating a lower electrode formation step according to the first example embodiment of the present invention.

FIG. 5 is a schematic sectional view illustrating a step of forming a wiring electrode for the lower electrode according to the first example embodiment of the present invention.

FIG. 6 is a schematic sectional view illustrating a first reinforcement film formation step according to the first example embodiment of the present invention.

FIG. 7 is a schematic sectional view illustrating a first intermediate layer formation step according to the first example embodiment of the present invention.

FIG. 8 is a schematic sectional view illustrating a sacrificial layer formation step according to the first example embodiment of the present invention.

FIG. 9 is a schematic sectional view illustrating a second intermediate layer formation step according to the first example embodiment of the present invention.

FIG. 10 is a schematic sectional view illustrating a support substrate attachment step according to the first example embodiment of the present invention.

FIG. 11 is a schematic sectional view illustrating a piezoelectric layer thickness reduction step according to the first example embodiment of the present invention.

FIG. 12 is a schematic sectional view illustrating an upper electrode formation step according to the first example embodiment of the present invention.

FIG. 13 is a schematic sectional view illustrating a second reinforcement film formation step according to the first example embodiment of the present invention.

FIG. 14 is a schematic sectional view illustrating a step of forming a wiring electrode for the upper electrode according to the first example embodiment of the present invention.

FIG. 15 is a schematic plan view showing an exemplary electrode provided on an upper surface of a piezoelectric layer according to a second example embodiment of the present invention.

FIG. 16 is a schematic plan view showing an exemplary electrode provided on the lower surface of the piezoelectric layer according to the second example embodiment of the present invention.

FIG. 17 is a schematic sectional view taken along line XVII-XVII in FIG. 15.

FIG. 18 is a circuit diagram showing a piezoelectric filter according to a third example embodiment of the present invention.

### DETAILED DESCRIPTION OF THE EXAMPLE EMBODIMENTS

Example embodiments of the present invention are described in detail below with reference to the drawings. The present invention is not limited to these example embodiments. Each of the example embodiments described herein is exemplary, and in modifications and second and subsequent example embodiments where the configurations can be partially replaced or combined between different example embodiments, only differing points are described, omitting descriptions of matters shared by the first example embodiment. Specifically, advantageous effects provided by the same or similar configurations are not described for every example embodiment.

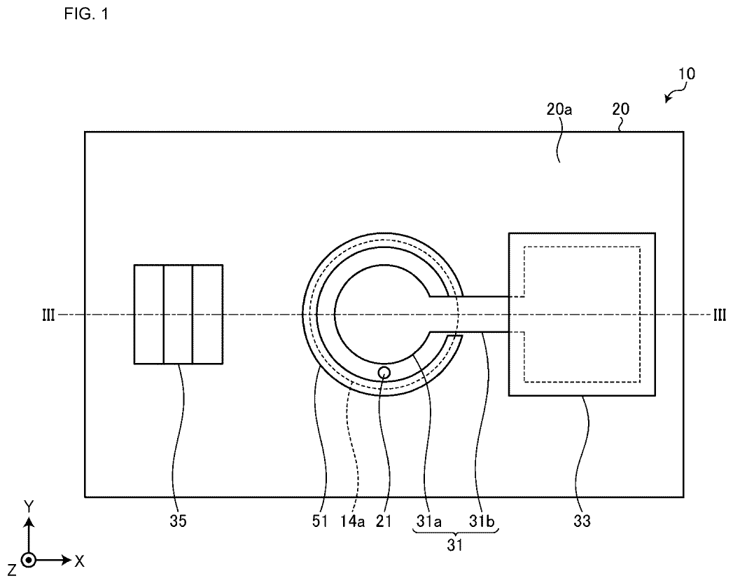

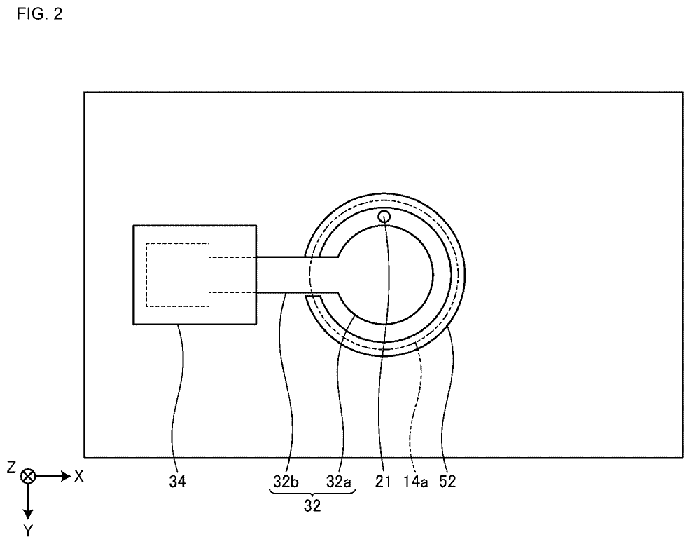

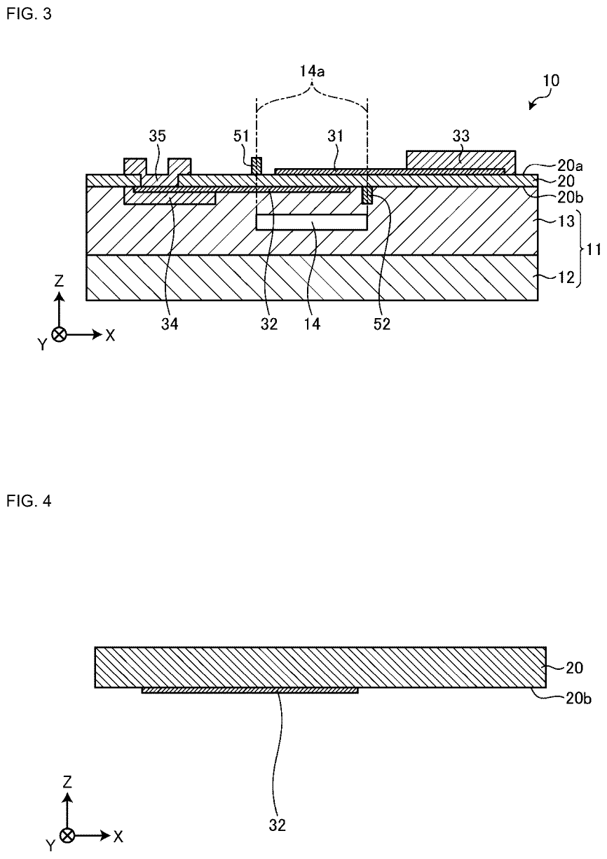

FIG. 1 is a schematic plan view showing an exemplary electrode provided on an upper surface of a piezoelectric layer according to a first example embodiment of the present invention. FIG. 2 is a schematic plan view showing an exemplary electrode provided on a lower surface of the piezoelectric layer according to the first example embodiment. FIG. 3 is a schematic sectional view taken along line III-III in FIG. 1. A piezoelectric device 10 according to the first example embodiment includes a support 11, a piezoelectric layer 20, an upper electrode 31, a wiring electrode 33 for the upper electrode, a lower electrode 32, wiring electrodes 34 and 35 for the lower electrode 32, and reinforcement films 51 and 52. The piezoelectric device 10 is a piezoelectric element that uses a bulk wave, e.g., a bulk acoustic wave (BAW) element. In the description below, a direction along the thickness of the support 11 is a Z-direction, a direction orthogonal or substantially orthogonal to the Z-direction is an X-direction, and a direction orthogonal or substantially orthogonal to the Z-direction and the X-direction is a Y-direction.

The piezoelectric layer 20 is a plate-shaped layer including an upper surface 20a and a lower surface 20b opposite to the upper surface 20a. The upper surface 20a is a first main surface of the piezoelectric layer 20. The lower surface 20b is a second main surface of the piezoelectric layer 20. In the first example embodiment, the piezoelectric layer 20 is a substrate made of single crystal capable of exciting a bulk wave, such as, for example, lithium niobate (LiNbO₃), lithium tantalate (LiTaO₃), or quartz crystal. Although there is no particular limitation on the thickness of the piezoelectric layer 20, for example, about 1 μm or below is preferable.

As shown in FIG. 1, the upper electrode 31 is provided on the upper surface 20a of the piezoelectric layer 20. The upper electrode 31 includes a circular electrode 31a and an electrode 31b extending from the circular electrode 31a in the X-direction. The wiring electrode 33 for the upper electrode is provided in the Z-direction of the electrode 31b. The wiring electrode 33 for the upper electrode is provided on the upper surface 20a side of the piezoelectric layer 20. The upper electrode 31 and the wiring electrode 33 for the upper electrode are made of metal such as, for example, aluminum (Al), platinum (Pt), copper (Cu), tungsten (W), or molybdenum (Mo) or an alloy including any of them. The upper electrode 31 and the wiring electrode 33 for the upper electrode may include an adhesion layer made of, for example, titanium (Ti), a nickel-chromium alloy (NiCr), or the like.

As shown in FIG. 2, the lower electrode 32 is provided on the lower surface 20b of the piezoelectric layer 20. The lower electrode 32 includes a circular electrode 32a and an electrode 32b extending from the circular electrode 32a in the X-direction. The wiring electrode 34 for the lower electrode is provided in the Z-direction of the electrode 32b. The wiring electrode 34 for the lower electrode is provided on the lower surface 20b side of the piezoelectric layer 20. The wiring electrode 35 for the lower electrode is provided on the upper surface 20a side of the piezoelectric layer 20 and penetrates through the piezoelectric layer 20. The lower electrode 32 and the wiring electrodes 34 and 35 for the lower electrode are made of metal or an alloy including, for example, Al, Pt, Cu, W, Mo, or the like. The lower electrode 32 and the wiring electrodes 34 and 35 for the lower electrode may include an adhesion layer made of, for example, Ti, NiCr, or the like.

In the first example embodiment, the circular electrode 31a of the upper electrode 31 and the circular electrode 32a of the lower electrode 32 overlap in plan view seen in the Z-direction. In other words, the piezoelectric layer 20 is sandwiched by the circular electrode 31a of the upper electrode 31 and the circular electrode 32a of the lower electrode 32. Thus, a bulk wave is propagated in an excitation region, i.e., a region between the circular electrode 31a of the upper electrode 31 and the circular electrode 32a of the lower electrode 32. The shape of the upper electrode 31 and the lower electrode 32 is merely exemplary and is not limited to this.

The support 11 faces the lower surface 20b of the piezoelectric layer 20. In the first example embodiment, the support 11 includes a support substrate 12 and an intermediate layer 13. The support substrate 12 is a substrate made of, for example, silicon (Si), quartz crystal, or the like. The intermediate layer 13 is a layer provided on the piezoelectric layer 20 side of the support substrate 12 and is made of a dielectric such as, for example, silicon oxide. The support 11 may not include the intermediate layer 13 and may include support substrate 12. Also, an adhesion layer made of, for example, Ti, NiCr, or the like may be present between the support substrate 12 and the intermediate layer 13.

The support 11 includes a space portion 14. In the first example embodiment, the space portion 14 is in the intermediate layer 13. As shown in FIGS. 2 and 3, the space portion 14 is provided so as to overlap with the excitation region in plan view seen in the Z-direction. This causes a bulk wave to be reflected by the space portion 14. In the example in FIG. 3, the space portion 14 is a void inside the intermediate layer 13 and surrounded by the intermediate layer 13 when seen in the Z-direction and a direction intersecting with the Z-direction, but the space portion 14 is not limited to this. For example, the space portion 14 may be a depressed internal void provided at the piezoelectric layer 20 side of the intermediate layer 13, may pass through the intermediate layer 13, may be a depressed internal void in the support substrate 12, or may pass through the support 11.

In the following description, a border 14a between a region overlapping with the space portion 14 and a region not overlapping with the space portion 14 in plan view seen in the Z-direction is described as the border 14a of the space portion. The region overlapping with the space portion 14 in plan view seen in the Z-direction is circular in the example in FIG. 1, but this is merely an example. The region may have a different shape and be, for example, rectangular.

The piezoelectric layer 20 includes a through-hole 21 communicating with the space portion 14. The through-hole 21 is at a position overlapping with the space portion 14 in plan view seen in the Z-direction. Although the through-hole 21 is provided between the upper electrode 31 and the reinforcement film 51 in the present example embodiment in FIGS. 1 to 3, the position of the through-hole 21 is not limited to this as long as the through-hole 21 is provided at a position overlapping with the space portion 14. The through-hole 21 may be provided so as to pass through the circular electrodes 31a and 32a of the upper electrode 31 and the lower electrode 32.

The reinforcement films 51 and 52 overlap with at least a portion of the border 14a of the space portion in plan view seen in the Z-direction. What is meant by overlapping with the border 14a of the space portion in plan view seen in the Z-direction is to lie astride a region overlapping with the space portion 14 and a region not overlapping with the space portion 14 in plan view seen in the Z-direction. In the example embodiment in FIGS. 1 and 2, the reinforcement film 51 is, for example, in the shape of the letter C (a chipped ring) and is shaped to extend along the border 14a of the space portion so as not to overlap with the electrode 31b of the upper electrode 31 extending in the X-direction. Similarly, the reinforcement film 52 is, for example, in the shape of the letter C and is shaped to extend along the border 14a of the space portion so as not to overlap with the electrode 32b of the lower electrode 32 extending in the X-direction. The reinforcement films 51 and 52 supports the portion of the piezoelectric layer 20 at the border 14a of the space portion, thus reducing or preventing the piezoelectric layer 20 from being cracked and damaged at the border 14a of the space portion. Although one of the end portions of the reinforcement film 51 in a direction along the border 14a is connected to the upper electrode 31 and one of the end portions of the reinforcement film 52 in a direction along the border 14a is connected to the lower electrode 32 in the example embodiment in FIGS. 1 and 2, this is merely an example. The reinforcement films 51 and 52 may be provided so as to overlap with the upper electrode 31 or the lower electrode 32, and do not have to be directly connected to the upper electrode 31 or the lower electrode 32.

The reinforcement films 51 and 52 are provided at the main surface of the piezoelectric layer 20. The reinforcement film 51 is provided on the upper surface 20a of the piezoelectric layer 2. The reinforcement film 52 is provided on the lower surface 20b of the piezoelectric layer 2. Although the single reinforcement film 51 and the single reinforcement film 52 are provided respectively on the upper surface 20a and the lower surface 20b of the piezoelectric layer 2 in the example embodiment in FIGS. 1 to 3, the configurations of the reinforcement film are not limited to this. A reinforcement film may be provided on one of the upper surface 20a and the lower surface 20b, or a plurality of reinforcement films may be provided on the same surface. Also, in the example embodiment in FIG. 2, the reinforcement film 52 is provided so as to be embedded in the intermediate layer 13 and spaced away from the space portion 14 in the Z-direction toward the piezoelectric layer 2. The reinforcement film 52 may be exposed to the space portion 14. The reinforcement film 52 is provided so as to overlap with the border 14a of the space portion in this case as well. Specifically, at the opposite side of the reinforcement film 52 from the piezoelectric layer 2 in the Z-direction, there is a wall surface (side surface) of the space portion 14 overlapping with the border 14a of the space portion, and the reinforcement film 52 is not in contact with the bottom surface of the space portion 14.

The reinforcement films 51 and 52 are conductive. What is meant by being conductive is to include a conductor. A conductor is, for example, a metal or an alloy including Al, Pt, Cu, W, Mo, or the like. The reinforcement films 51 and 52 may each be a multilayered film including a plurality of layers, in which case at least one of the plurality of layers may be a layer made of a conductor. Also, the reinforcement films 51 and 52 may each include an adhesion layer made of, for example, Ti, NiCr, or the like.

The conductive reinforcement films 51 and 52 are electrically connected to the upper electrode 31 or the lower electrode 32. In the example embodiment in FIGS. 1 and 2, the reinforcement film 51 is connected to the upper electrode 31, and the reinforcement film 52 is connected to the lower electrode 32. This generates an electrical capacitance between the reinforcement film 51 and the reinforcement film 52 when the piezoelectric device 10 is driven and enables adjustment of the frequency characteristics of the piezoelectric device 10. The reinforcement film 51 and the reinforcement film 52 may have different film thicknesses from each other. When the reinforcement film 51 and the reinforcement film 52 thus have asymmetric film thicknesses, unwanted waves generated in the piezoelectric device 10 can be reduced or prevented.

The piezoelectric device of the first example embodiment has been described above, but the piezoelectric device of the first example embodiment is not limited to the one described above.

For example, the reinforcement films do not have to be conductive. Also, the reinforcement films do not have to be electrically connected to the upper electrode 31 or the lower electrode 32. Even in this case, the reinforcement films support the portion of the piezoelectric layer 20 at the border 14a of the space portion and can reduce or prevent the piezoelectric layer 20 from being cracked and damaged.

Also, the piezoelectric layer 20 may have different thicknesses between the region overlapping with the reinforcement films 51 and 52 and the region where the upper electrode 31 and the lower electrode 32 overlap (the excitation region) in plan view seen in the Z-direction. For example, the thickness of the piezoelectric layer 20 in the excitation region may be larger than the thickness of the piezoelectric layer 20 in a region outside the excitation region. In this case, a propagation wave can be trapped in the excitation region, so that generation of a leaky wave can be reduced.

As described above, the piezoelectric device 10 according to the first example embodiment includes the piezoelectric layer 20 including a thickness in a first direction and including the upper surface 20a as one of surfaces in the first direction and the lower surface 20b as another one of the surfaces in the first direction, the support 11 provided on a side of the lower surface 20b of the piezoelectric layer 20, the upper electrode 31 provided on the upper surface 20a of the piezoelectric layer 20, the lower electrode 32 provided on the lower surface 20b of the piezoelectric layer 20 with at least a portion of the lower electrode 32 facing the upper electrode 31, and the reinforcement films 51 and 52 provided on at least one of the upper surface 20a and the lower surface 20b of the piezoelectric layer 20. The support 11 includes the space portion 14 in a region overlapping with at least a portion of the upper electrode 31 and the lower electrode 32. The reinforcement films 51 and 52 overlap with at least a portion of the border 14a between a region overlapping with the space portion 14 and a region not overlapping with the space portion 14 in plan view seen in the first direction. The reinforcement films 51 and 52 thus support the portion of the piezoelectric layer 20 at the border 14a of the space portion and therefore help reduce or prevent the piezoelectric layer 20 from being cracked and damaged at the border 14a of the space portion.

Preferably, the reinforcement films 51 and 52 are provided on the upper surface 20a and the lower surface 20b. The reinforcement films 51 and 52 thus support the portion of the piezoelectric layer 20 at the border 14a of the space portion at the upper surface 20a and the lower surface 20b and therefore more effectively reduce or prevent the piezoelectric layer 20 from being cracked and damaged at the border 14a of the space portion.

More preferably, the reinforcement film 51 provided on the upper surface 20a and the reinforcement film 52 provided on the lower surface 20b are conductive. At least one of the reinforcement film 51 provided at the upper surface 20a and the reinforcement film 52 provided at the lower surface 20b is connected to at least one of the upper electrode 31 and the lower electrode 32. Because an electrical capacitance is thus generated between the reinforcement film 51 and the reinforcement film 52, adjustment of the frequency characteristics, such as an adjustment of a band width, can be performed.

Further preferably, the thickness of the reinforcement film 51 provided on the upper surface 20a and the thickness of the reinforcement film 52 provided on the lower surface 20b are different from each other. This enables propagation waves different between the reinforcement film 51 and the reinforcement film 52 to be trapped in the excitation region, and leakage of a propagation wave can be reduced or prevented with unwanted waves reduced.

Also, the thickness of the piezoelectric layer 20 in an area overlapping with the reinforcement film 51 provided on the upper surface 20a and the reinforcement film 52 provided on the lower surface 20b in plan view seen in the first direction and the thickness of the piezoelectric layer 20 in an area overlapping with the upper electrode 31 and the lower electrode 32 in plan view seen in the first direction are different from each other. Thus, a propagation wave can be trapped in the excitation region, so that leakage of a propagation wave can be reduced or prevented.

An example of a method for manufacturing the piezoelectric device 10 according to the first example embodiment is described below. The method for manufacturing the piezoelectric device according to the first example embodiment includes a lower electrode formation step, a first intermediate layer formation step, a sacrificial layer formation step, a second intermediate layer formation step, a support substrate attachment step, a piezoelectric layer thickness reduction step, an upper electrode formation step, and a space portion formation step.

FIG. 4 is a schematic sectional view illustrating the lower electrode formation step according to the first example embodiment. As shown in FIG. 4, the lower electrode formation step is a step of forming the lower electrode 32 on the lower surface 20b of the piezoelectric layer 20. The first example embodiment forms the lower electrode 32 by, for example, deposition lift-off involving formation of a patterned resist using photolithography, deposition of a metal film, and removal of the resist. After the formation of the lower electrode 32, the lower electrode 32 may be flattened at its surface opposite from the piezoelectric layer 20 using, for example, chemical mechanical polishing (CMP).

FIG. 6 is a schematic sectional view illustrating a step of forming a wiring electrode for the lower electrode according to the first example embodiment. As shown in FIG. 6, the step of forming a wiring electrode for the lower electrode is a step of forming the wiring electrode 34 for the lower electrode 32 on the lower surface 20b of the piezoelectric layer 20 so as to cover a portion of the lower electrode 32. The first example embodiment forms the wiring electrode 34 by, for example, deposition lift-off involving formation of a patterned resist using photolithography, deposition of a metal film, and removal of the resist. After the formation of the wiring electrode 34, the wiring electrode 34 may be flattened at its surface opposite from the piezoelectric layer 20 using, for example, chemical mechanical polishing (CMP).

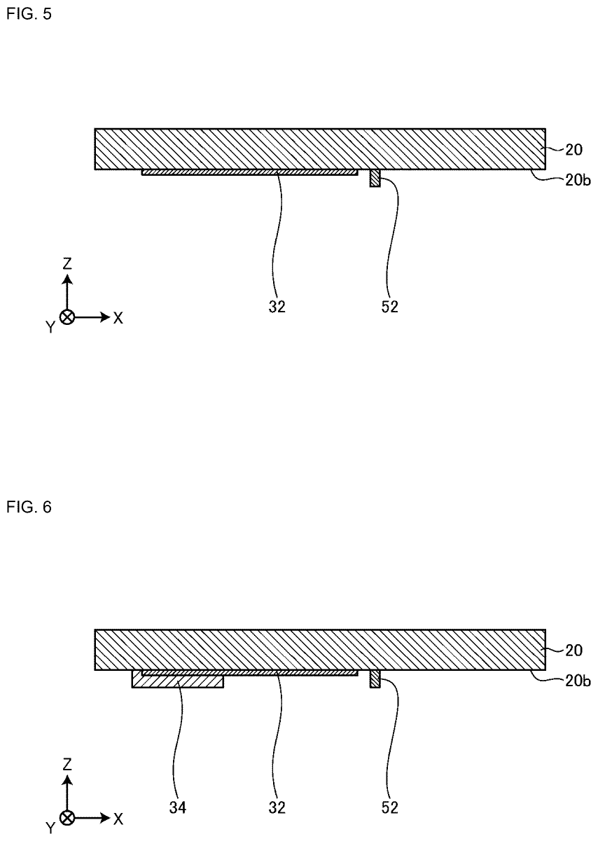

FIG. 5 is a schematic sectional view illustrating a first reinforcement film formation step according to the first example embodiment. As shown in FIG. 5, the first reinforcement film formation step is a step of forming the reinforcement film 52 on the lower surface 20b of the piezoelectric layer 20. The first example embodiment forms the reinforcement film 52 by, for example, deposition lift-off involving formation of a patterned resist using photolithography, deposition of a metal film, and removal of the resist. After the formation of the reinforcement film 52, the reinforcement film 52 may be flattened at its surface opposite from the piezoelectric layer 20 using, for example, chemical mechanical polishing (CMP).

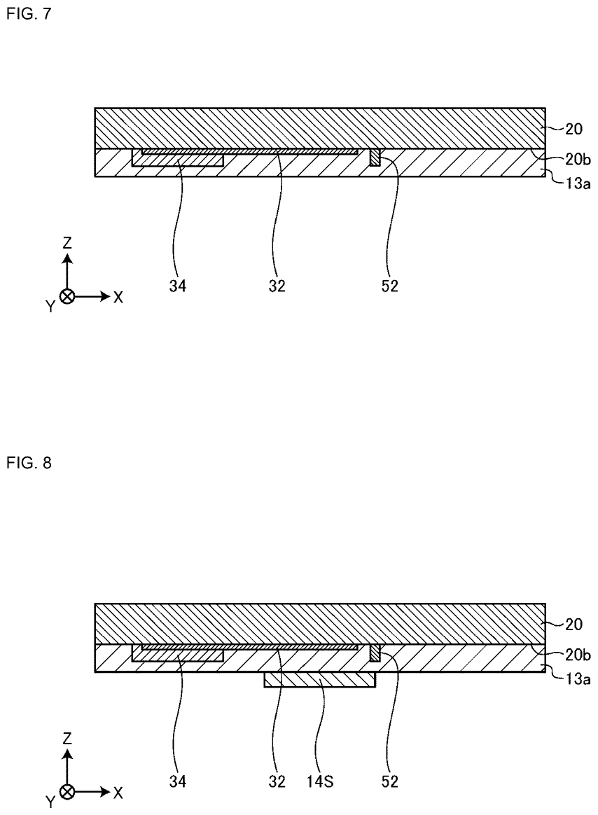

FIG. 7 is a schematic sectional view illustrating the first intermediate layer formation step according to the first example embodiment. As shown in FIG. 7, the first intermediate layer formation step is a step of forming an intermediate layer 13a at the lower surface 20b of the piezoelectric layer 20 so as to cover the lower electrode 32, the wiring electrode 34 for the lower electrode 32, and the reinforcement film 52. The first example embodiment forms the intermediate layer 13a by forming, for example, SiO₂ using sputtering and then flattening its surface opposite from the piezoelectric layer 20 using chemical mechanical polishing (CMP).

FIG. 8 is a schematic sectional view illustrating the sacrificial layer formation step according to the first example embodiment. As shown in FIG. 8, the sacrificial layer formation step is a step of forming a sacrificial layer 14S at the intermediate layer 13a at its surface opposite from the piezoelectric layer 2. In the first example embodiment, the sacrificial layer 14S is a layer made of, for example, zinc oxide and is formed by sputtering.

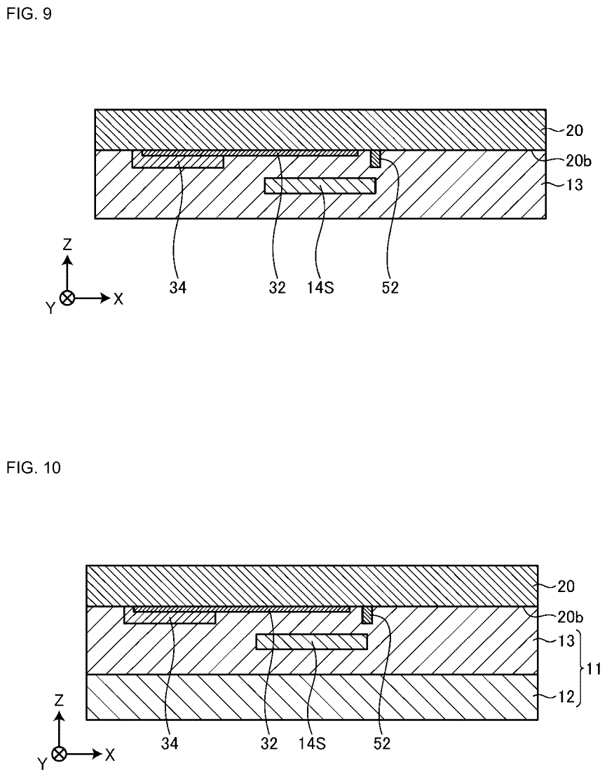

FIG. 9 is a schematic sectional view illustrating the second intermediate layer formation step according to the first example embodiment. As shown in FIG. 9, the second intermediate layer formation step is a step of forming the intermediate layer 13 by additionally forming an intermediate layer at the intermediate layer 13a at its surface opposite from the piezoelectric layer 2 so as to cover the sacrificial layer 14S. The first example embodiment forms the intermediate layer 13 by forming the intermediate layer 13 using, for example, sputtering and then flattening its surface opposite from the piezoelectric layer 20 using CMP.

FIG. 10 is a schematic sectional view illustrating the support substrate attachment step according to the first example embodiment. As shown in FIG. 10, the support substrate attachment step is a step of attaching the support substrate 12 to the intermediate layer 13 at its side opposite from the piezoelectric layer 20. The first example embodiment bonds the support substrate 12 to the intermediate layer 13 by, e.g., fusion bonding, direct bonding (SDB: Silicon wafer Direct Bonding), plasma-activated bonding, or atomic diffusion bonding.

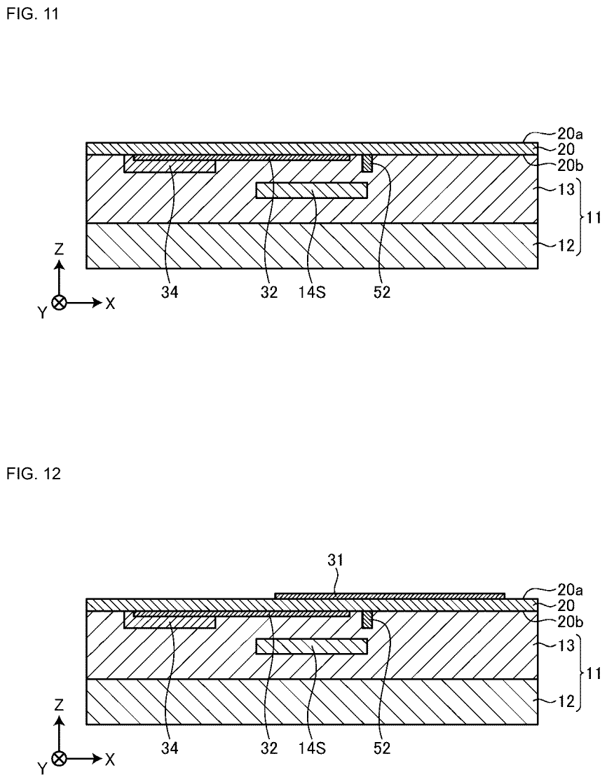

FIG. 11 is a schematic sectional view illustrating the piezoelectric layer thickness reduction step according to the first example embodiment. As shown in FIG. 11, the piezoelectric layer thickness reduction step is a step of forming the upper surface 20a by reducing the thickness of the piezoelectric layer 20. The first example embodiment reduces the thickness of the piezoelectric layer 20 using, for example, grinding or CMP, but the piezoelectric layer thickness reduction step is not limited to this. For example, the piezoelectric layer 20 may be reduced in thickness as follows: forming a damage layer inside the piezoelectric layer 20 by ion implantation and exfoliating a layer at the upper surface of the damage layer thus formed.

FIG. 12 is a schematic sectional view illustrating the upper electrode formation step according to the first example embodiment. As shown in FIG. 12, the upper electrode formation step is a step of forming the upper electrode 31 at the upper surface 20a of the piezoelectric layer 20. The first example embodiment forms the upper electrode 31 by, for example, deposition lift-off involving formation of a patterned resist using photolithography, deposition of a metal film, and removal of the resist. After being formed, the upper electrode 31 may be subjected to CMP to be flattened at its surface opposite from the piezoelectric layer 20.

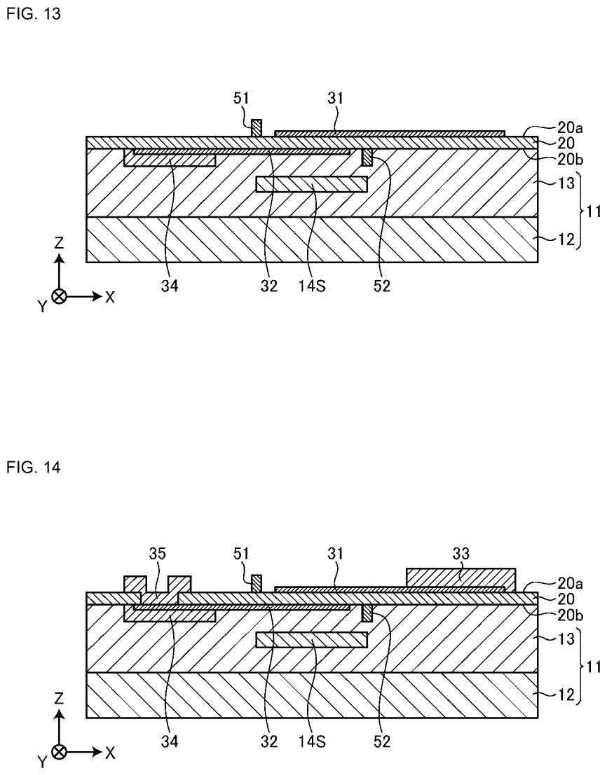

FIG. 13 is a schematic sectional view illustrating a second reinforcement film formation step according to the first example embodiment. As shown in FIG. 13, the second reinforcement film formation step is a step of forming the reinforcement film 51 at the upper surface 20a of the piezoelectric layer 20. The first example embodiment forms the reinforcement film 51 by, for example, deposition lift-off involving formation of a patterned resist using photolithography, deposition of a metal film, and removal of the resist. After being formed, the reinforcement film 51 may be subjected to CMP to be flattened at its surface opposite from the piezoelectric layer 20.

FIG. 14 is a schematic sectional view illustrating a step of forming the wiring electrode for the upper electrode and the lower electrode according to the first example embodiment. As shown in FIG. 14, the step of forming the wiring electrode for the upper electrode and the lower electrode is a step of forming the wiring electrode 35 for the lower electrode 32 and the wiring electrode 33 for the upper electrode 31. More specifically, an opening is formed at a position overlapping with the lower electrode 32 in plan view seen in the Z-direction to pass through the piezoelectric layer 20 in the Z-direction, and the wiring electrode 35 is formed at the upper surface 20a of the piezoelectric layer 20 so as to cover the lower electrode 32 exposed through the opening. As a result, the wiring electrode 35 draws the lower electrode 32 out to the upper surface 20a of the piezoelectric layer 20. Also, the wiring electrode 33 is formed at the upper surface 20a of the piezoelectric layer 20 so as to cover a portion of the upper electrode 31. The first example embodiment forms the opening in the piezoelectric layer 20 by removing a portion of the piezoelectric layer 20 using, for example, reactive ion etching (RIE). Also, the first example embodiment forms the wiring electrodes 33 and 35 by, for example, deposition lift-off involving formation of a patterned resist using photolithography, deposition of a metal film, and removal of the resist. After being formed, the wiring electrodes 33 and 35 may be subjected to CMP to be flattened at their surfaces opposite from the piezoelectric layer 20.

After that, the space portion formation step is performed. The space portion formation step is a step of forming the space portion 14 by removing the sacrificial layer 14S. The first example embodiment forms the space portion 14 by removing the sacrificial layer 14S using wet etching that involves provision of a through-hole (not shown) in the piezoelectric layer 20 and injection of an etchant that dissolves the sacrificial layer 14S through the through-hole 21. In this case, the through-hole is provided at a position overlapping with the sacrificial layer 14S in plan view seen in the Z-direction. In the first example embodiment, the through-hole is formed using RIE, for example.

As a result of the above steps, the piezoelectric device 10 according to the first example embodiment is fabricated. The method for manufacturing the piezoelectric device 10 described above is merely an example, and the method is not limited to what is described above. The steps may be changed as needed.

For example, the reinforcement film 52 may be formed simultaneously with the lower electrode 32 in the lower electrode formation step or may be formed simultaneously with the wiring electrode 34 in the step of forming the wiring electrode for the lower electrode. Also, the reinforcement film 51 may be formed simultaneously with the upper electrode 31 in the upper electrode formation step or may be formed simultaneously with the wiring electrodes 33 and 35 in the step of forming a wiring electrode for the upper electrode.

For example, in a case where only the reinforcement film 51 is provided and the reinforcement film 52 is not provided, the first reinforcement film formation step is not performed. Similarly, in a case where only the reinforcement film 52 is formed and the reinforcement film 51 is not provided, the second reinforcement film formation step is not performed.

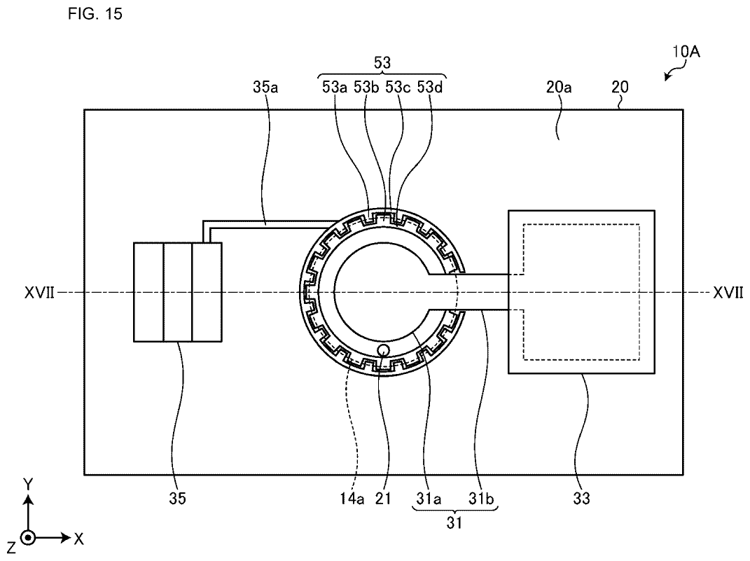

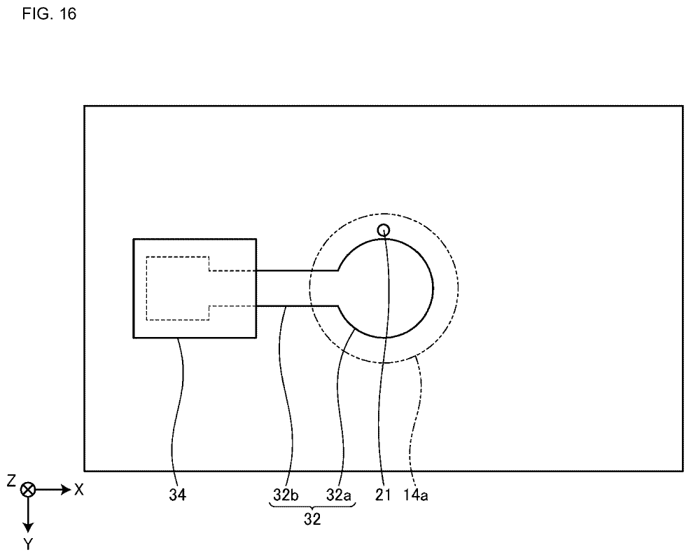

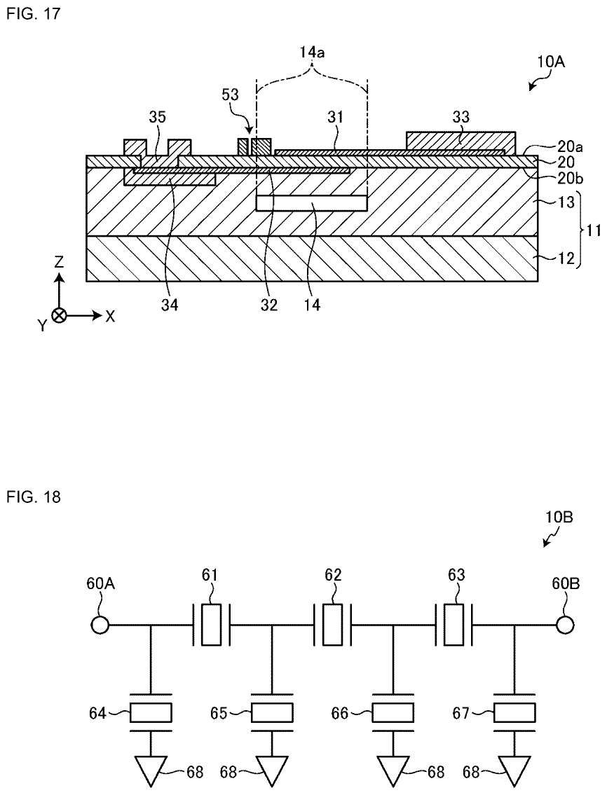

FIG. 15 is a schematic plan view showing an exemplary electrode provided on the upper surface of a piezoelectric layer according to a second example embodiment of the present invention. FIG. 16 is a schematic plan view showing an exemplary electrode provided at the lower surface of the piezoelectric layer according to the second example embodiment. FIG. 17 is a schematic sectional view taken along line XVII-XVII in FIG. 15. As shown in FIG. 15, a piezoelectric device 10A according to the second example embodiment differs from that of the first example embodiment in that a reinforcement film 53 is a comb-shaped electrode.

The reinforcement film 53 according to the second example embodiment is, as shown in FIGS. 15 and 17, provided on the upper surface 20a of the piezoelectric layer 2. The reinforcement film according to the second example embodiment may be provided on the lower surface 20b of the piezoelectric layer 2 or may be provided on the upper surface 20a and the lower surface 20b of the piezoelectric layer 2. In a case where the reinforcement film according to the second example embodiment is provided on the lower surface 20b of the piezoelectric layer 2, the reinforcement film may be embedded in the intermediate layer 13 or may be exposed to the space portion 14.

The reinforcement film 53 according to the second example embodiment is, as shown in FIG. 15, a comb-shaped electrode including first electrode fingers 53a, second electrode fingers 53b, a first busbar 53c, and a second busbar 53d. Specifically, the reinforcement film 53 includes a first reinforcement film including the first electrode fingers 53a and the first busbar 53c and a second reinforcement film including the second electrode fingers 53b and the second busbar 53d. Here, the first electrode fingers 53a are an example of the “first comb-tooth portions,” the second electrode fingers 53b are an example of the “second comb-tooth portions,” the first busbar 53c is the “first extension portion,” and the second busbar 53d is an example of the “second extension portion.” This reduces or prevents delamination from the piezoelectric layer 20 and therefore more effectively reduces or prevents the piezoelectric layer 20 from being cracked and damaged at the border 14a of the space portion.

In the second example embodiment, the reinforcement film 53 is electrically connected to at least one of the upper electrode 31 or the lower electrode 32. In the example embodiment in FIG. 15, the first busbar 53c is electrically connected to the lower electrode 32 via the wiring electrode 35 and a wiring electrode 35a. The second busbar 53d is electrically connected to the upper electrode 31. As a result, an electrical capacitance is generated between the first electrode fingers 53a and the second electrode fingers 53b when the piezoelectric device 10A is driven, which enables adjustment of the characteristics of the piezoelectric device 10A to control the band width or the like.

The first electrode fingers 53a extend in a direction intersecting with the border 14a and are connected to the first busbar 53c at their ends on one side in the extension direction. The second electrode fingers 53b extend in a direction intersecting with the border 14a and are connected to the second busbar 53d at their ends on the other side in the extension direction. The plurality of first electrode fingers 53a and the plurality of second electrode fingers 53b are arrayed alternately along the border 14a with gaps therebetween.

The first busbar 53c and the second busbar 53d are each in the shape of the letter C and shaped to extend along the border 14a so as not to overlap with the electrode 31b of the upper electrode 31 extending in the X-direction. The first busbar 53c and the second busbar 53d are spaced away from each other so as to face each other in a direction intersecting with the border 14a. In the example embodiment in FIG. 15, the first busbar 53c is provided at a position not overlapping with the space portion 14 in plan view seen in the Z-direction. Meanwhile, the second busbar 53d is provided at a position overlapping with the space portion 14 in plan view seen in the Z-direction. In other words, the plurality of first electrode fingers 53a and the plurality of second electrode fingers 53b are arrayed between the first busbar 53c and the second busbar 53d.

In the example embodiment in FIG. 15, both ends of the second busbar 53d in the direction along the border 14a are connected to the electrode 31b of the upper electrode 31 extending in the X-direction, and both ends of the first busbar 53c in the direction along the border 14a are provided not to be connected to the upper electrode 31 and are connected to the lower electrode 32. This, however, is merely an example, and the reinforcement films 53 may be provided so as to overlap with the upper electrode 31 or the lower electrode 32 and do not have to be directly connected to the upper electrode 31 or the lower electrode 32.

In the example embodiment in FIG. 15, a region (an intersecting region) where the first electrode fingers 53a and the second electrode fingers 53b adjacent to each other overlap as seen from a direction orthogonal or substantially orthogonal to the direction in which the first electrode fingers 53a and the second electrode fingers 53b extend overlaps with the border 14a of the space portion 14 in plan view seen in the Z-direction. This enables distribution of unwanted waves in a region overlapping with the space portion 14 and a region not overlapping with the space portion 14 in plan view seen in the Z-direction.

Although the piezoelectric device 10A according to the second example embodiment has been described above, the piezoelectric device according to the second example embodiment is not limited to the one described above. The following describes modifications thereof.

In a piezoelectric device according to a first modification of the second example embodiment, the intersecting region is inward of the border 14a of the space portion 14 in plan view seen in the Z-direction. Specifically, in the first modification, in plan view seen in the Z-direction, the first electrode fingers 53a, the second electrode fingers 53b, and the second busbar 53d overlap with the space portion 14, while the first busbar 53c overlaps with the border 14a of the space portion. This facilitates control of unwanted waves.

In a piezoelectric device according to a second modification of the second example embodiment, the intersecting region is outward of the border 14a of the space portion 14 in plan view seen in the Z-direction. Specifically, in the second modification, in plan view seen in the Z-direction, the first electrode fingers 53a, the second electrode fingers 53b, and the first busbar 53c do not overlap with the space portion 14, while the second busbar 53d overlaps with the border 14a of the space portion. This helps reduce or prevent unwanted waves in the region overlapping with the space portion 14.

As described above, in the piezoelectric device 10A according to the second example embodiment, the reinforcement film 53 includes a first reinforcement film and a second reinforcement film. The first reinforcement film and the second reinforcement film are on the same surface of the piezoelectric layer 20 and face each other in a direction intersecting with the first direction and the border 14a. The reinforcement film 53 thus supports the portion of the piezoelectric layer 20 at the border 14a of the space portion with the reinforcement film being smaller in area than the reinforcement film 51 according to the first example embodiment, and therefore helps reduce or prevent the piezoelectric layer 20 from being cracked and damaged at the border 14a of the space portion.

The first reinforcement film includes the first extension portion (the first busbar 53c) and the plurality of first comb-tooth portions (the first electrode fingers 53a) whose base ends are connected to the first extension portion. The second reinforcement film includes the second extension portion (the second busbar 53d) and the plurality of second comb-tooth portions (the second electrode fingers 53b) whose base ends are connected to the second extension portion. This helps reduce or prevent delamination of the reinforcement film 53 from the piezoelectric layer 20, and therefore more effectively helps reduce or prevent the piezoelectric layer 20 from being cracked and damaged at the border 14a of the space portion.

The first reinforcement film and the second reinforcement film are conductive. At least one of the first reinforcement film and the second reinforcement film is connected to at least one of the upper electrode 31 and the lower electrode 32. The added capacitance enables adjustment of the frequency characteristics.

More preferably, the region (the intersecting region) where the plurality of first comb-tooth portions and the plurality of second comb-tooth portions adjacent to each other overlap when seen in a direction in which the plurality of first comb-tooth portions and the plurality of second comb-tooth portions are arrayed is in a region overlapping with the space portion 14 in plan view seen in the first direction. This facilitates control of unwanted waves.

More preferably, the region (the intersecting region) where the plurality of first comb-tooth portions and the plurality of second comb-tooth portions adjacent to each other overlap when seen in a direction in which the first comb-tooth portions and the second comb-tooth portions are arrayed is in a region not overlapping with the space portion 14 in plan view seen in the first direction. This reduces or prevents unwanted waves in the excitation region.

More preferably, the region (the intersecting region) where the plurality of first comb-tooth portions and the plurality of second comb-tooth portions adjacent to each other overlap when seen in a direction in which the plurality of first comb-tooth portions and the plurality of second comb-tooth portions are arrayed overlaps with the border 14a in plan view seen in the first direction. This enables distribution of unwanted waves.

FIG. 18 is a circuit diagram showing a piezoelectric filter according to a third example embodiment of the present invention. As shown in FIG. 18, a piezoelectric filter 10B according to the third example embodiment includes a plurality of series arm resonators 61, 62, and 63 and a plurality of parallel arm resonators 64, 65, 66, and 67. The plurality of series arm resonators 61, 62, and 63 are connected in series to a signal path between an input terminal 60A and an output terminal 60B. The plurality of parallel arm resonators 64, 65, 66, and 67 are connected in parallel between a ground 68 and the signal path between the input terminal 60A and the output terminal 60B. The piezoelectric filter 10B according to the third example embodiment is a ladder filter.

The plurality of series arm resonators 61, 62, and 63 connected in series are at one terminal electrically connected to the input terminal 60A and are at the other terminal electrically connected to the output terminal 60B. The parallel arm resonator 64 is at one terminal electrically connected to the input terminal 60A and is at the other terminal electrically connected to the ground 68. The parallel arm resonator 65 is at one terminal electrically connected to a signal path connecting the series arm resonator 61 and the series arm resonator 62 and is at the other terminal electrically connected to the ground 68. The parallel arm resonator 66 is at one terminal electrically connected to a signal path connecting the series arm resonator 62 and the series arm resonator 63 and is at the other terminal electrically connected to the ground 68. The parallel arm resonator 67 is at one terminal electrically connected to the output terminal 60B and is at the other terminal electrically connected to the ground 68.

In the present example embodiment, at least one of the plurality of series arm resonators 61, 62, and 63 and the plurality of parallel arm resonators 64, 65, 66, and 67 is the piezoelectric device according to the first example embodiment or the second example embodiment. In the present example embodiment, the plurality of series arm resonators 61, 62, and 63 have different configurations of reinforcement films from the plurality of parallel arm resonators 64, 65, 66, and 67, so as to be able to obtain a better output waveform as a filter.

As described above, the piezoelectric filter 10B according to the third example embodiment is a filter device including at least one resonator. The resonator is the piezoelectric device 10 according to the first example embodiment or the piezoelectric device 10A according to the second example embodiment. Even in this case, it is possible to help reduce or prevent the piezoelectric layer 20 from being cracked and damaged at the border 14a of the space portion.

Preferably, the piezoelectric filter 10B includes the input terminal 60A, the output terminal 60B, a series arm connecting the input terminal and the output terminal, and a parallel arm connecting a node on the series arm and the ground 68. The at least one resonator includes a plurality of resonators and includes the series arm resonators 61, 62, and 63 provided at the series arm and the parallel arm resonators 64, 65, 66, and 67 provided at the parallel arm. This enables a better output waveform as a filter to be obtained.

The example embodiments described above have been provided to facilitate understanding of the present invention, not for the present invention to be interpreted in a limited manner. The present invention may be changed or improved without departing from the scope and gist thereof, and the present invention includes such equivalents as well.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoelectric device comprising:
a piezoelectric layer including a thickness in a first direction, and an upper surface defining one of surfaces in the first direction and a lower surface defining another one of the surfaces in the first direction;
a support on a side of the lower surface of the piezoelectric layer;
an upper electrode on the upper surface of the piezoelectric layer;
a lower electrode on the lower surface of the piezoelectric layer with at least a portion of the lower electrode facing the upper electrode; and
a reinforcement film on at least one of the upper surface and the lower surface of the piezoelectric layer; wherein
the support includes a space portion in a region overlapping with at least a portion of the upper electrode and the lower electrode; and
in plan view seen in the first direction, the reinforcement film overlaps with at least a portion of a border between a region overlapping with the space portion and a region not overlapping with the space portion.

2. The piezoelectric device according to claim 1, wherein the reinforcement film is on the upper surface and the lower surface.

3. The piezoelectric device according to claim 2, wherein
the reinforcement film on the upper surface and the reinforcement film on the lower surface are conductive; and
at least one of the reinforcement film on the upper surface and the reinforcement film on the lower surface is connected to at least one of the upper electrode and the lower electrode.

4. The piezoelectric device according to claim 3, wherein a thickness of the reinforcement film on the upper surface and a thickness of the reinforcement film on the lower surface are different from each other.

5. The piezoelectric device according to claim 3, wherein, in plan view seen in the first direction, a thickness of the piezoelectric layer in an area overlapping with the reinforcement film on the upper surface and the reinforcement film on the lower surface and a thickness of the piezoelectric layer in an area overlapping with the upper electrode and the lower electrode are different from each other.

6. The piezoelectric device according to claim 1, wherein
the reinforcement film includes a first reinforcement film and a second reinforcement film; and
the first reinforcement film and the second reinforcement film are at a same surface of the piezoelectric layer and face each other in a direction intersecting with the first direction and the border.

7. The piezoelectric device according to claim 6, wherein
the first reinforcement film includes a first extension portion and a plurality of first comb-tooth portions including base ends connected to the first extension portion; and
the second reinforcement film includes a second extension portion and a plurality of second comb-tooth portions including base ends connected to the second extension portion.

8. The piezoelectric device according to claim 7, wherein
the first reinforcement film and the second reinforcement film are conductive; and
at least one of the first reinforcement film and the second reinforcement film is connected to at least one of the upper electrode and the lower electrode.

9. The piezoelectric device according to claim 8, wherein a region where the plurality of first comb-tooth portions and the plurality of second comb-tooth portions adjacent to each other overlap when seen in a direction in which the plurality of first comb-tooth portions and the plurality of second comb-tooth portions are arranged is located in a region overlapping with the space portion in plan view seen in the first direction.

10. The piezoelectric device according to claim 8, wherein a region where the plurality of first comb-tooth portions and the plurality of second comb-tooth portions adjacent to each other overlap when seen in a direction in which the plurality of first comb-tooth portions and the plurality of second comb-tooth portions are arranged is located in a region not overlapping with the space portion in plan view seen in the first direction.

11. The piezoelectric device according to claim 8, wherein a region where the plurality of first comb-tooth portions and the plurality of second comb-tooth portions adjacent to each other overlap when seen in a direction in which the plurality of first comb-tooth portions and the plurality of second comb-tooth portions are arranged overlaps with the border in plan view seen in the first direction.

12. A piezoelectric filter comprising:
a filter device including at least one resonator; wherein
the resonator includes piezoelectric device according to claim 1.

13. The piezoelectric filter according to claim 12, further comprising:
an input terminal;
an output terminal;
a series arm connecting the input terminal and the output terminal; and
a parallel arm connecting a node on the series arm and a ground; wherein
the at least one resonator includes a plurality of resonators, and a series arm resonator at the series arm and a parallel arm resonator at the parallel arm.

14. The piezoelectric filter according to claim 12, wherein the reinforcement film is on the upper surface and the lower surface.

15. The piezoelectric filter according to claim 14, wherein
the reinforcement film on the upper surface and the reinforcement film on the lower surface are conductive; and
at least one of the reinforcement film on the upper surface and the reinforcement film on the lower surface is connected to at least one of the upper electrode and the lower electrode.

16. The piezoelectric filter according to claim 15, wherein a thickness of the reinforcement film on the upper surface and a thickness of the reinforcement film on the lower surface are different from each other.

17. The piezoelectric filter according to claim 15, wherein, in plan view seen in the first direction, a thickness of the piezoelectric layer in an area overlapping with the reinforcement film on the upper surface and the reinforcement film on the lower surface and a thickness of the piezoelectric layer in an area overlapping with the upper electrode and the lower electrode are different from each other.

18. The piezoelectric filter according to claim 12, wherein
the reinforcement film includes a first reinforcement film and a second reinforcement film; and
the first reinforcement film and the second reinforcement film are at a same surface of the piezoelectric layer and face each other in a direction intersecting with the first direction and the border.

19. The piezoelectric filter according to claim 18, wherein
the first reinforcement film includes a first extension portion and a plurality of first comb-tooth portions including base ends connected to the first extension portion; and
the second reinforcement film includes a second extension portion and a plurality of second comb-tooth portions including base ends connected to the second extension portion.

20. The piezoelectric filter according to claim 18, wherein
the first reinforcement film and the second reinforcement film are conductive; and
at least one of the first reinforcement film and the second reinforcement film is connected to at least one of the upper electrode and the lower electrode.
